(19) United States
(12) Patent Application Publication
(10) Pub. No.: US 2016/0202762 A1
(43) Pub. Date: Jul. 14, 2016

(54) TOUCH PANEL TYPE INPUT DEVICE, AND TOUCH PANEL TYPE INPUT METHOD

(71) Applicant: DENSO CORPORATION, Aichi (JP)

(72) Inventors: Tetsuya TOMARU, Kariya-city (JP); Shinji HATANAKA, Nishio-city (JP)

(21) Appl. No.: 14/910,053

(22) PCT Filed: Aug. 4, 2014
(86) PCT No.: PCT/JP2014/004059

§ 371 Date: Feb. 4, 2016

(30) Foreign Application Priority Data
Aug. 9, 2013 (JP) 2013-166204

(51) Int. Cl. G06F 3/01

(52) U.S. Cl. CPC G06F 3/016

(57) ABSTRACT

A touch panel type input device includes: a display unit that displays multiple input-enabled regions, on which a finger of a user is touchable; an input device that performs an input corresponding to one of the input-enabled regions when the finger touches the one of the input-enabled regions; and a first approach notification device that executes a first approach notification for notifying the user of an approach of the finger when the finger is disposed within a first predetermined distance from the one of the input-enabled regions without touching the display unit. The first approach notification device executes the first approach notification by vibrating a part of a compartment of a vehicle other than the input device.

### CROSS REFERENCE TO RELATED APPLICATION

This application is based on Japanese Patent Application No. 2013-166204 filed on Aug. 9, 2013, the disclosure of which is incorporated herein by reference.

### TECHNICAL FIELD

The present disclosure relates to a touch panel type input device and a touch panel type input method, in which a user's touch of a predetermined region of a display unit is detected, and an input corresponding to the touch is thus performed.

### BACKGROUND ART

Touch panel type input devices are known in which, when a user's touch of a predetermined region (input-enabled region) of a display unit on which various types of content are displayed is detected as in smartphones or car navigation systems, an input (touch input) corresponding to the input-enabled region is performed. In such touch panel type input devices, a touch input is performed by a touch to the input-enabled region of the display unit, and thus an intuitive operation can be performed, but it is difficult to touch the input-enabled region while the display unit (input-enabled region) is not visually observed.

Consequently, the following technique is proposed in order to easily perform a touch input in a state where a display unit is not visually observed. That is, a finger moves on the display unit in a state where the finger is brought in touch with the display unit, and a vibration is given to the finger when the finger reaches an input-enabled region (notice is given of the finger touching the input-enabled region). A technique is proposed in which a touch input is performed by pressing a finger against the display unit in a state where the finger touches the input-enabled region (Patent Literature 1).

However, the technique proposed above has a problem in that the difficulty of a touch input in a state where the display unit is not visually observed is not able to be sufficiently reduced. This is based on the following reasons.

First, in the proposed technique, it is determined whether the input-enabled region is just searched for or a touch input is performed, on the basis of whether the finger softly touches or strongly presses the display unit. However, since the position of the display unit has to be searched for by touch in state where the display unit is not visually observed, a case may occur in which the finger strongly presses the display unit unconsciously. In addition, while a user is careful in not strongly pressing the display unit even after the display unit has been found out by touch, the finger is required to slide on the surface of the display unit, and thus it is not easy to perform such an operation without visually observing the display unit. As a result, the finger strongly presses the input-enabled region unintentionally, which leads to an erroneous touch input.

### PRIOR ART LITERATURES

### Patent Literature

Patent Literature 1: Japanese Patent 4896932 B

### SUMMARY OF INVENTION

It is an object of the present disclosure to provide a touch panel type input device and a touch panel type input method, which easily performs a touch input without visually observing a display unit.

According to a first aspect of the present disclosure, a touch panel type input device includes: a display unit that displays a plurality of input-enabled regions, on which a finger of a user is touchable; an input device that performs an input corresponding to one of the input-enabled regions when it is detected that the finger touches the one of the input-enabled regions; and a first approach notification device that executes a first approach notification for notifying the user of an approach of the finger when the finger is disposed within a first predetermined distance from the one of the input-enabled regions without touching the display unit. The first approach notification device executes the first approach notification by vibrating a part of a compartment of a vehicle other than the input device.

In the input device, even when the user does not visually observe the display unit by receiving the first approach notification, the user can recognize the position of the input-enabled region without touching the display unit. The user can perform an input (touch input) corresponding to the input-enabled region by touching the input-enabled region of the display unit from this state (state the position of the input-enabled region is recognized). As a result, a case does not occur in which an erroneous touch input is performed, and thus a touch input can be easily performed even when the display unit is not visually observed.

According to a first aspect of the present disclosure, a touch panel type input method for a display unit that displays a plurality of input-enabled regions, on which a finger of a user is touchable, includes: performing an input corresponding to one of the input-enabled regions when it is detected that the finger touches the one of the input-enabled regions; and executing a first approach notification for notifying the user of an approach of the finger when the finger is disposed within a first predetermined distance from the one of the input-enabled regions without touching the display unit. The executing of the first approach notification includes vibrating a part of a compartment of a vehicle other than a touch panel type device.

In the input method, even when the user does not visually observe the display unit, by receiving the first approach notification, the user can recognize the position of the input-enabled region without touching the display unit. The user can perform an input (touch input) corresponding to the input-enabled region by touching the input-enabled region of the display unit from this state (state the position of the input-enabled region is recognized). As a result, a case does not occur in which an erroneous touch input is performed, and thus a touch input can be easily performed even when the display unit is not visually observed.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram illustrating a configuration of a touch panel type input device 10;

FIG. 2 is a diagram illustrating contents which are displayed on a display screen of a liquid crystal display 16;

FIG. 3 is a flow diagram illustrating a touch input process which is executed by a CPU 11;

FIG. 4 is a flow diagram illustrating an approach handling process which is executed by the CPU 11;

FIGS. 5A and 5B are diagrams illustrating a state where the position of a driver's finger is detected;

FIG. 6 is a diagram conceptually illustrating a vibration pattern table;

FIG. 7 is a flow diagram illustrating a touch handling process which is executed by the CPU 11;

FIG. 8 is a flow diagram illustrating an approach handling process of a first modification example;

FIG. 9 is a diagram illustrating a state where the position of a driver's finger of the first modification example is detected; and

FIG. 10 is a flow diagram illustrating a touch panel approach handling process of a second modification example.

### EMBODIMENTS FOR CARRYING OUT INVENTION

Hereinafter, an embodiment of a touch panel type input device will be described in order to clarify contents the present disclosure mentioned above. Meanwhile, a touch panel type input device 10 of the present embodiment is provided in a vehicle.

### A. DEVICE CONFIGURATION

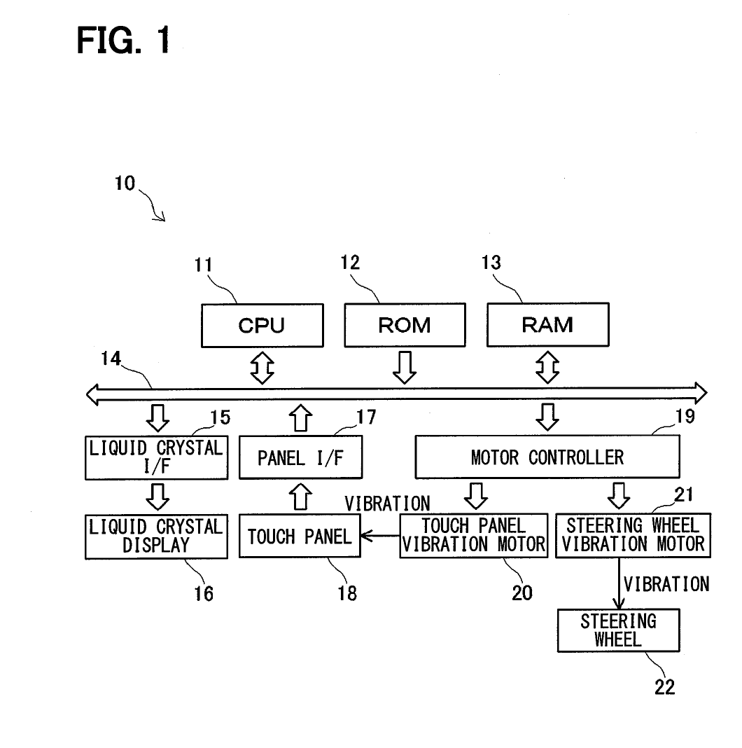

FIG. 1 illustrates a configuration of the touch panel type input device 10. As shown in the drawing, the touch panel type input device 10 of the present embodiment is configured such that, with a central focus on a CPU 11, a ROM 12 in which programs and the like executed by the CPU 11 are stored and a RAM 13 which is a work area of the CPU 11 are connected to each other through a bus 14.

In addition, a liquid crystal display 16 which is provided in an instrument panel of a vehicle is connected to the bus 14 through a liquid crystal interface 15. In addition, a touch panel 18 capable of detecting an approach and a touch of a driver's finger is superimposed on a display screen of the liquid crystal display 16, and the touch panel 18 is connected to the bus 14 through a panel interface 17.

In addition, a touch panel vibration motor 20 for vibrating the touch panel 18 and a steering vibration motor 21 for vibrating a steering 22 of a vehicle are connected to the bus 14 through a motor controller 19. The touch panel vibration motor 20 and the steering vibration motor 21 have weights installed thereon so as to be eccentric to each rotating shaft, and vibrate the touch panel 18 and the steering 22 by the rotation thereof.

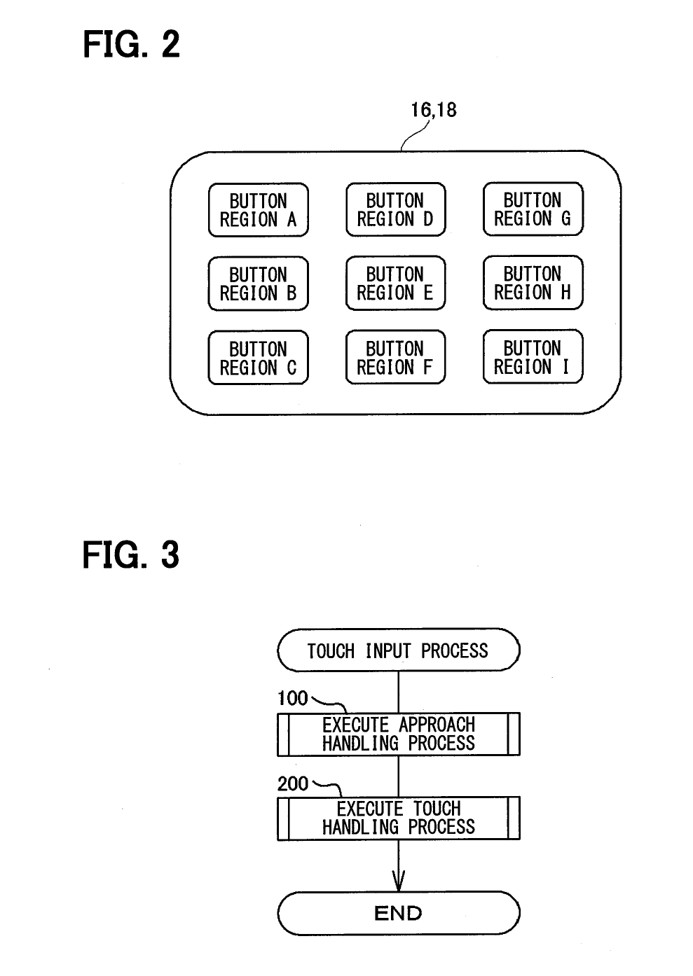

FIG. 2 illustrates an image which is displayed on the liquid crystal display 16 which is superimposed on the touch panel 18. As shown in the drawing, in the touch panel type input device 10 of the present embodiment, button type items capable of being selected by a driver are displayed on the liquid crystal display 16. When a driver's finger touches regions of the touch panel 18 corresponding to the button type items (hereinafter, referred to as “button regions”), inputs corresponding to the button regions are performed.

### B. TOUCH INPUT PROCESS

FIG. 3 illustrates a flow diagram of a touch input process which is executed by the CPU 11. The touch input process is started up when the button type items are displayed on the liquid crystal display 16, and is executed as a timer interruption process for each predetermined time (for example, 4 ms). As shown in the drawing, in the touch input process, an “approach handling process (S100)” relating to the driver's finger approaching (not touching but locating within a predetermined distance) the button region and a “touch handling process (S200)” relating to the driver's finger touching the button region are performed.

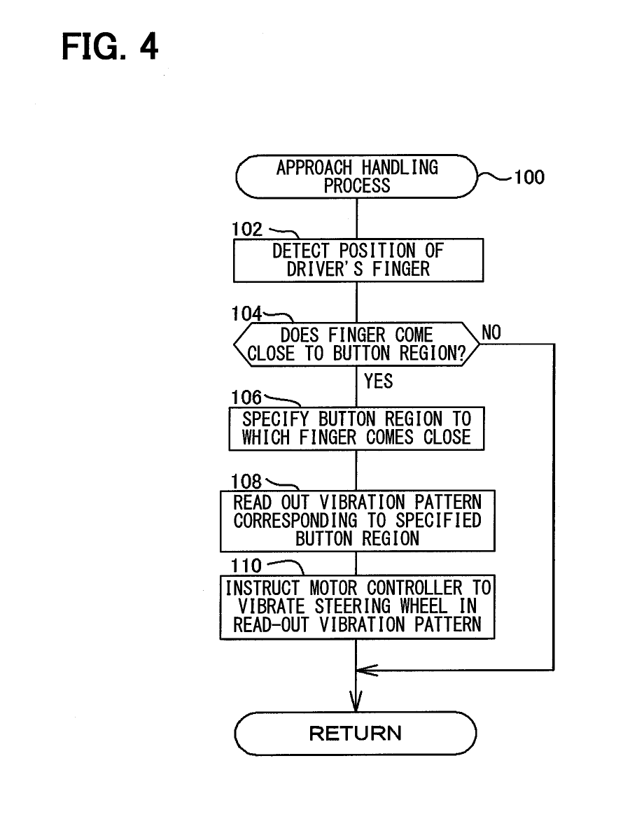

FIG. 4 illustrates a flow diagram of the approach handling process (S100). When the approach handling process is started, first, CPU 11 detects the position of the driver's finger (S102). The position of the driver's finger is detected as follows.

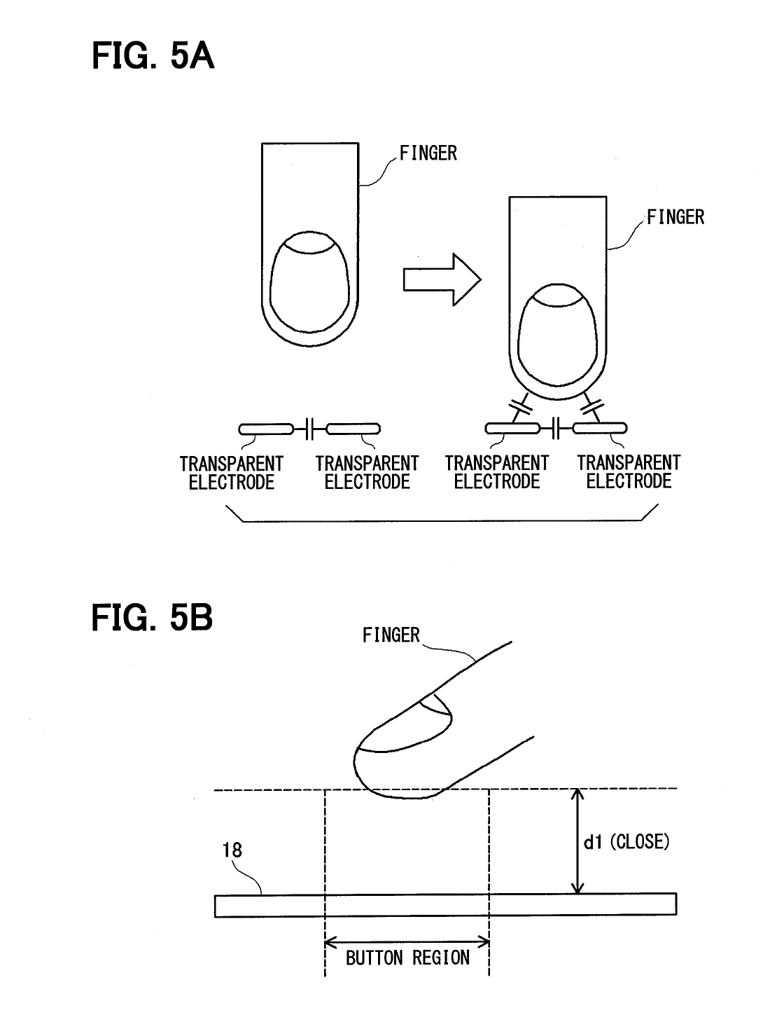

FIG. 5 illustrates a state where the position of the driver's finger is detected. As the touch panel 18 of the present embodiment, a projection-type capacitance touch panel having transparent electrodes arranged lengthwise and crosswise are adopted. As shown in FIG. 5A, when the driver's finger comes close to the touch panel 18, capacitive coupling between the finger and the transparent electrodes occurs, a capacitance between the transparent electrodes changes in association therewith. The amount of change in capacitance between the transparent electrodes corresponds to a distance between the finger and the transparent electrodes. Consequently, the position of the driver's finger is detected on the basis of the amount of change in capacitance between the transparent electrodes and the position of a transparent electrode having a change in capacitance occurring therein.

In this manner, as a result of detecting the position of the driver's finger (S102), it is determined, as shown in FIG. 5B, whether the driver's finger is located within a distance d1 (first predetermined distance, for example, 20 to 30 mm) from any button region of the button regions which are displayed on the liquid crystal display 16, and is in a state of not being in touch with the button region (state where the driver's finger comes close to any button region) (S104). As a result, when the driver's finger does not come close to any button region (S104: no), the approach handling process shown in FIG. 4 is terminated as it is, and the flow returns to the touch input process shown in FIG. 3. On the other hand, when the driver's finger comes close to any button region (S104: yes), a button region to which the finger comes close is specified (any of button regions A to I is specified in the example shown in FIG. 2) (S106). A vibration pattern corresponding to the button region specified (to which the finger comes close) is then read out (S108).

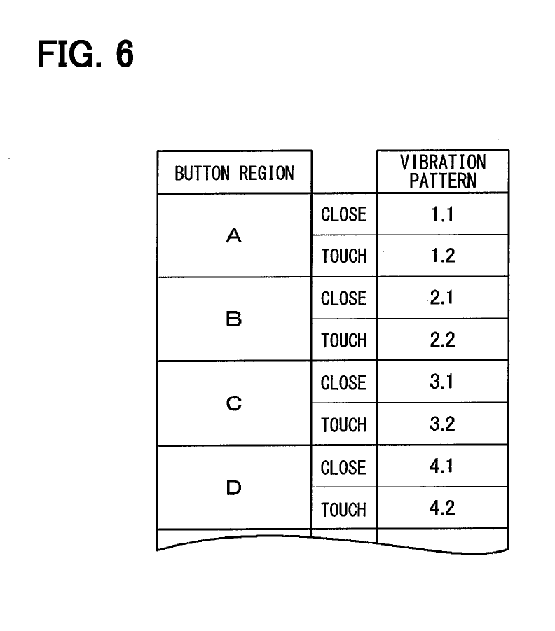

FIG. 6 conceptually illustrates a vibration pattern table which is stored in a predetermined address of the RAM 13. In the touch panel type input device 10 of the present embodiment, the steering 22 is vibrated when the driver's finger comes close to the button region, and the touch panel 18 is vibrated when the driver's finger touches the button region. The vibration pattern refers to vibration modes (for example, vibration waveforms) in these cases. As shown in the drawing, in the vibration pattern table, the vibration pattern is stored in association with the type of button region, and by division between a case where the finger comes close to the button region and a case the finger is in touch therewith.

In a process of S108 of FIG. 4, the vibration pattern when the driver's finger comes close to the button region specified in the process of S106 is read out with reference to the above-mentioned vibration pattern table. A steering vibration instruction signal for instructing the motor controller 19 “to vibrate the steering 22 in the read-out vibration pattern” is then transmitted to the motor controller (S110). When such a steering vibration instruction signal is received, the motor controller 19 controls an operation of the steering vibration motor 21 so that the steering 22 vibrates in the vibration pattern as instructed by the signal.

In this manner, when the steering vibration instruction signal is transmitted to the motor controller 19, the approach handling process shown in FIG. 4 is terminated, and the flow returns to the touch input process shown in FIG. 3.

As described above, in the touch panel type input device 10 of the present embodiment, when the driver's (user's) finger comes close to the button region (input-enabled region), the steering 22 is vibrated (first approach notification device that issues a first approach notification). Therefore, even when the driver does not visually observe the display screen of the liquid crystal display 16, the driver can recognize the position of the button region without touching the touch panel 18.

In addition, in the touch panel type input device 10 of the present embodiment, the vibration pattern of the steering 22 is made different depending on the type of button region to which the driver's finger comes close, and thus the type of button region to which the finger comes close can be easily recognized.

Meanwhile, the display screen of the liquid crystal display 16 and the touch panel 18 in the present embodiment correspond to a “display unit” in the present disclosure.

In this manner, when the approach handling process is performed (S100 of FIG. 3), the touch handling process is performed subsequently (S200).

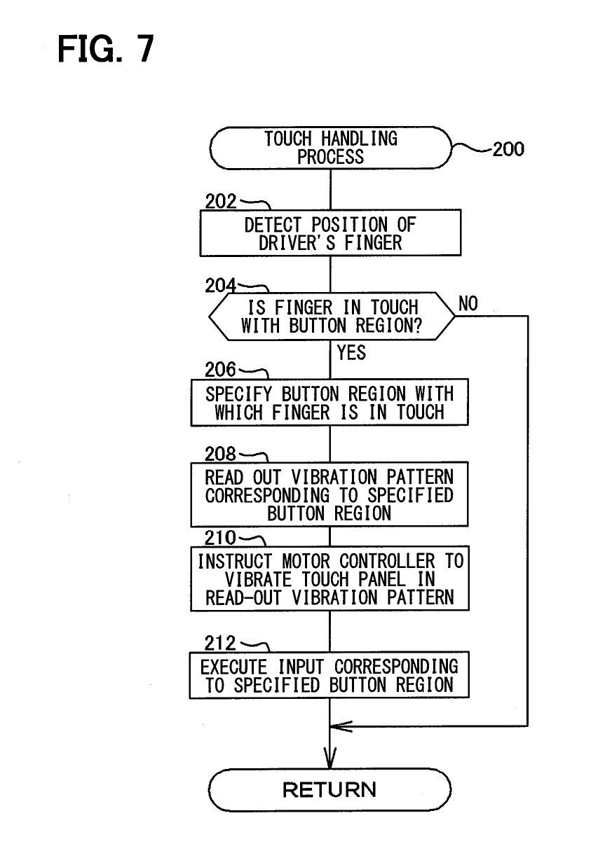

FIG. 7 illustrates a flow diagram of the touch handling process (S200). When the touch handling process is started, first, the CPU 11 detects the position of the driver's finger (S202). That is, the position of the driver's finger is detected on the basis of the amount of change in capacitance between the transparent electrodes and the position of a transparent electrode having a change in capacitance occurring therein, as described above, with reference to FIG. 5A.

In this manner, as a result of detecting the position of the driver's finger (S202), it is determined whether the driver's finger touches any button region of the button regions on the display screen of the liquid crystal display 16 (S204). As a result, when the driver's finger does not touch any button region (S204: no), the approach handling process shown in FIG. 7 is terminated as it is, and the flow returns to the touch input process shown in FIG. 3. On the other hand, when the driver's finger comes close to any button region (S204: yes), a button region to which the finger comes close is specified (any of the button regions A to I is specified in the example shown in FIG. 2) (S206). The vibration pattern when the driver's finger touches the specified button region is then read out with reference to the above-mentioned vibration pattern table in FIG. 6 (S208). Subsequently, a touch panel vibration instruction signal for instructing the motor controller 19 “to vibrate the touch panel 18 in the read-out vibration pattern” is transmitted to the motor controller (S110). When such a touch panel vibration instruction signal is received, the motor controller 19 controls an operation of the touch panel vibration motor 20 so that the touch panel 18 vibrates in the vibration pattern as instructed by the signal.

In this manner, when the steering vibration instruction signal is transmitted to the motor controller 19, an input corresponding to the button region specified in the process of S206 (button region with which the driver's finger is in touch) is executed. For example, characters or numerals which are displayed on the button region are input, or contents associated with the menu items which are displayed on the button region are displayed. The touch handling process shown in FIG. 7 is then terminated, the flow returns to the touch input process shown in FIG. 3.

As described above, in the touch panel type input device 10 of the present embodiment, the steering 22 is vibrated when the driver's finger comes close to a button region, and an input corresponding to the button region is performed when the driver's finger touches the button region (input device). Therefore, even when the driver does not visually observe the liquid crystal display 16 by receiving a first approach notification, the driver can recognize the position of the button region without touching the touch panel 18. In addition, the driver can touch a button region by touching the touch panel 18 in this state (state where the position of the button region is recognized), and can perform an input (touch input) corresponding to the button region. As a result, a case does not occur in which an erroneous touch input is performed, and thus a touch input can be easily performed even when the liquid crystal display 16 is not visually observed.

In addition, in the touch panel type input device 10 of the present embodiment, when the driver's finger touches the button region, the touch panel 18 is vibrated (touch notification device that issues a touch notification), and therefore it is possible to easily recognize that the finger touches the button region, and that an input corresponding to the button region is performed.

In addition, in the touch panel type input device 10 of the present embodiment, since the vibration pattern of the touch panel 18 is made different depending on the type of button region with which the driver's finger is in touch, the type of button region with which the finger is in touch can be easily recognized.

Meanwhile, modes to be adopted in which the vibration pattern is made different include various modes such as a mode in which the vibration time is made different, a mode in which the magnitude of vibration (size of the amplitude of a vibration waveform) is made different, and a mode in which the number of vibrations is made different.

### C. MODIFICATION EXAMPLE

### C-1. First Modification Example

In the above-mentioned embodiment, when the driver's finger comes close to the button region, the steering 22 is vibrated in a predetermined vibration pattern. However, when the driver's finger comes close to the button region, the steering 22 may be vibrated in a vibration pattern depending on a distance between the driver's finger and the button region.

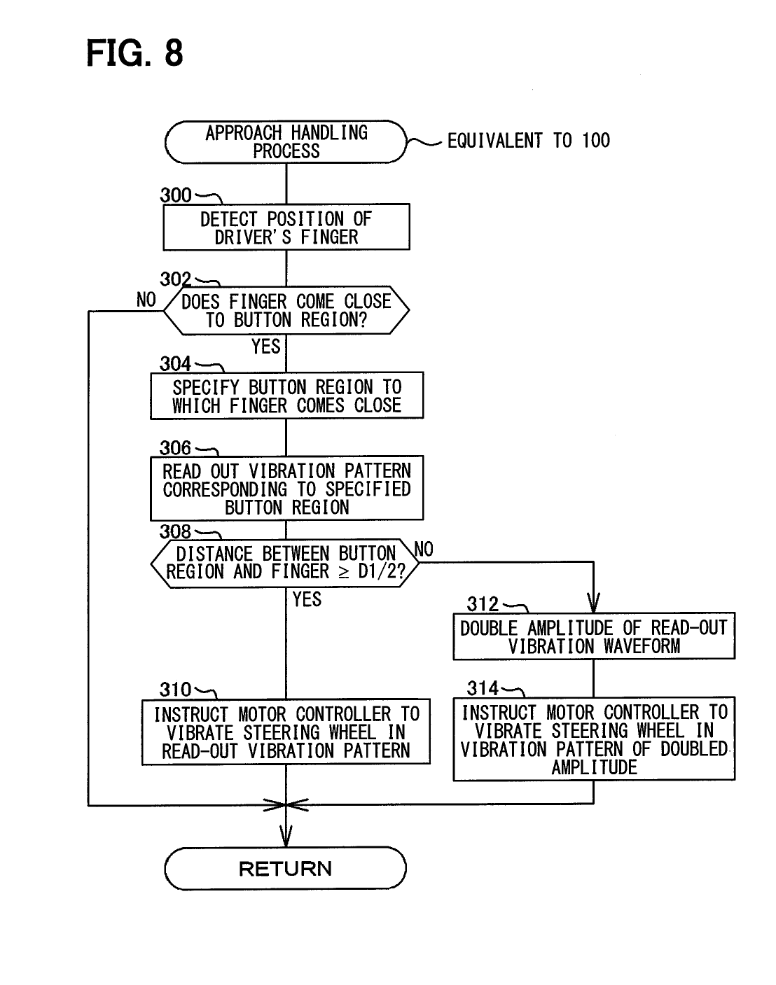

FIG. 8 illustrates a flow diagram of an approach handling process of a first modification example. In the first modification example, the approach handling process shown in FIG. 8 is performed as the approach handling process (S100) shown in FIG. 3. When the approach handling process is started in the first modification example, first, the CPU 11 detects the position of the driver's finger on the basis of the amount of change in capacitance between the transparent electrodes of the touch panel 18 and the position of a transparent electrode having a change in capacitance occurring therein (S300). As a result of detecting the position of the driver's finger (S300), it is determined whether the driver's finger comes close to any button region (S302). As a result, when the driver's finger does not come close to any button region (S302: no), the approach handling process shown in FIG. 8 is terminated as it is, and the flow returns to the touch input process shown in FIG. 3. On the other hand, when the driver's finger comes close to any button region (S302: yes), a button region to which the finger comes close is specified (any of the button regions A to I is specified in the example shown in FIG. 2) (S304). The vibration pattern when the driver's finger comes close to the specified button region is then read out with reference to the above-mentioned vibration pattern table in FIG. 6 (S306).

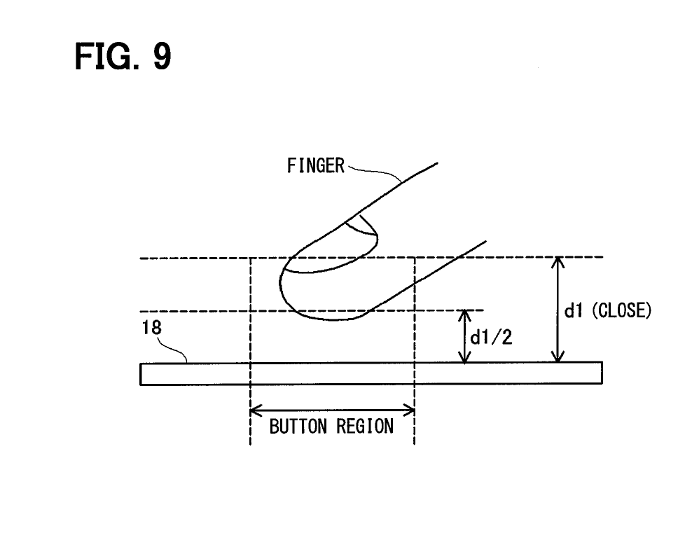

Subsequently, it is determined whether a distance between the button region specified in the process of S304 and the driver's finger is equal to or greater than half (d1/2) of the distance d1 (S308). In the first modification example, as is the case with the aforementioned embodiment, with reference to FIG. 5B, it is determined that the driver's finger is located within the distance d1 from the button region, and that the driver's finger comes close to the button region when the finger does not touch the button region. In the determination process of S308, as shown in FIG. 9, it is determined whether the driver's finger is in a state of being away from the button region by a distance d1/2 or more, or the driver's finger is in a state of coming closer to the button region from this state and a distance to the button region is less than the distance d1/2, among states where the driver's finger comes close to the button region.

As a result of the determination process of S308, when the driver's finger comes close to the button region, but a distance to the button region is still equal to or greater than the distance d1/2 (S308: yes), a steering vibration instruction signal for instructing the motor controller 19 “to vibrate the steering 22 in the vibration pattern read out in the process of S306” is transmitted to the motor controller (S310). On the other hand, when a distance from the driver's finger to the button region is less than half of the distance d1 (S308: no), calculation of doubling the amplitude of the vibration pattern read out in the process of S306 is performed (S312). A steering vibration instruction signal for instructing the motor controller 19 “to vibrate the steering 22 in the vibration pattern obtained by doubling the amplitude” is transmitted to the motor controller (S314).

When these steering vibration instruction signals are received, the motor controller 19 controls an operation of the steering vibration motor 21 so that the steering 22 vibrates in the vibration pattern as instructed by the signals. That is, when the driver's finger comes close to the button region, but a distance to the button region is still equal to or greater than the distance d1/2, the steering 22 is vibrated in the vibration pattern read out in the process of S306. When the driver's finger comes closer to the button region and the distance to the button region is less than the distance d1/2, the steering 22 is vibrated in the vibration pattern obtained by doubling the amplitude of the vibration pattern read out in the process of S306.

As described above, in the first modification example, when the driver's finger comes close to the button region, the steering 22 is vibrated in the vibration pattern depending on the distance between the driver's finger and the button region, and thus the distance to the button region can be easily recognized when the finger comes close to the button region.

In addition, in a state where the driver's finger comes close to the button region, the magnitude of the vibration of the steering 22 becomes larger when the finger comes close to the button region (the steering 22 is vibrated in the vibration pattern obtained by doubling the amplitude), and thus the driver can feel that finger comes close to the button region.

### C-2. Second Modification Example

In the above-mentioned embodiment, when the driver's finger comes close to the button region, the steering 22 is vibrated in a predetermined vibration pattern. However, in addition thereto, when the driver's finger does not come close to the button region nor is in touch therewith, but comes close to the touch panel 18, the steering 22 may be vibrated in a predetermined vibration pattern.

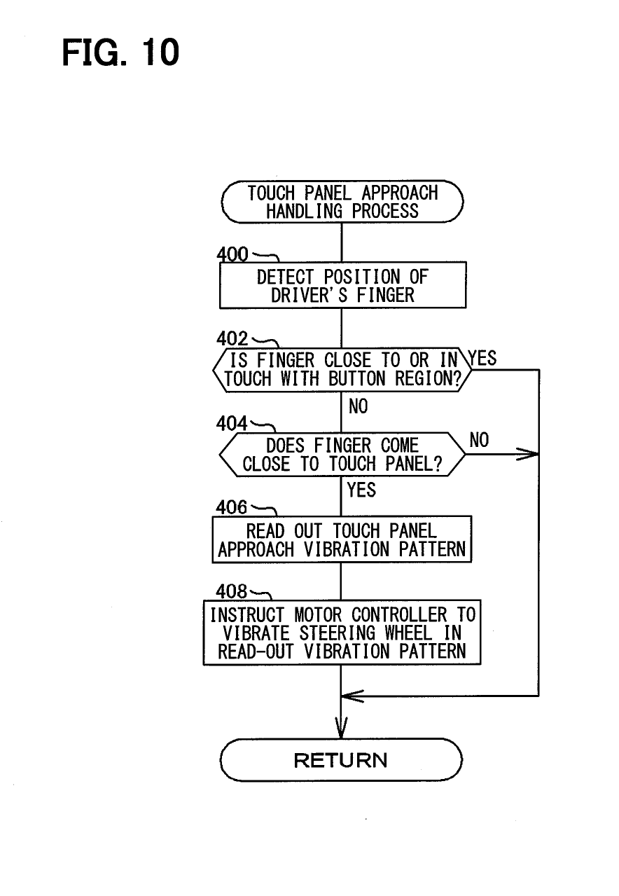

FIG. 10 illustrates a flow diagram of a touch panel approach handling process of a second modification example. In the second modification example, the touch panel approach handling process of the second modification example is performed in advance of the approach handling process (S100) shown in FIG. 3.

When the touch panel approach handling process is started in the second modification example, first, the CPU 11 detects the position of the driver's finger on the basis of the amount of change in capacitance between the transparent electrodes of the touch panel 18 and the position of a transparent electrode having a change in capacitance occurring therein (S400). As a result of detecting the position of the driver's finger (S400), it is determined whether the driver's finger becomes close to any button region or is in touch therewith (S402). As a result, when the driver's finger becomes close to any button region or is in touch therewith (S402: yes), the touch panel approach handling process shown in FIG. 10 is terminated as it is. That is, when the driver's finger becomes close to any button region or is in touch therewith, the touch panel approach handling process corresponds to the approach handling process (S100 of FIG. 3) or the touch handling process (S200 of FIG. 3), the process is terminated as it is.

On the other hand, when the driver's finger does not become close to any button region nor comes close thereto (S402: no), it is determined whether the driver's finger is located within a distance d2 (second predetermined distance, distance d2>distance d1) from the touch panel 18, and is in a state of not being in touch with the touch panel 18 (state where the driver's finger comes close to the touch panel 18) (S404). As a result, the driver's finger does not comes close to the touch panel 18 (S404: no), the touch panel approach handling process shown in FIG. 10 is terminated as it is.

On the other hand, when the driver's finger comes close to the touch panel 18 (S404: yes), the vibration pattern when the driver's finger comes close to the touch panel 18 (touch panel approach vibration pattern) is read out. This touch panel approach vibration pattern is smaller in the magnitude of vibration (smaller in the amplitude of a vibration waveform) than the vibration pattern in a case of coming close to the button region. In addition, the touch panel approach vibration pattern may be stored as a portion of the vibration pattern table described above with reference to FIG. 6, and may be stored separately from the table.

In this manner, when the touch panel approach vibration pattern is read out (S406), a steering vibration instruction signal for instructing the motor controller 19 “to vibrate the steering 22 in the read-out touch panel approach vibration pattern” is transmitted to the motor controller (S408). When such a steering vibration instruction signal is received, the motor controller 19 controls an operation of the steering vibration motor 21 so that the steering 22 vibrates in the touch panel approach vibration pattern.

As described above, in the second modification example, even when the driver's finger comes close to the touch panel 18, the steering 22 is vibrated (second approach notification device that issues a second approach notification), and thus the driver can recognize the position of the touch panel 18 without visually observing the touch panel 18.

In addition, in the second modification example, the steering 22 is vibrated in a state where the finger is away from the touch panel 18 (distance d2), rather than in a case where the steering 22 is vibrated (distance d1) when the finger comes close to the button region. Therefore, the driver can recognize the position of the button region after the driver first recognizes the position of the touch panel 18, and thus can feel that the finger gradually becomes close to the button region.

Further, in the second modification example, in a case where the finger comes close to the touch panel 18 rather than in a case where the finger comes close to the button region, the vibration of the steering 22 becomes smaller. Therefore, the vibration of the steering 22 can be increased as the driver's finger come closer to the button region after the finger comes close to the touch panel 18, and a feeling of the finger coming close to the button region can be further emphasized.

As stated above, although the touch panel type input device 10 of the embodiment and the modification examples has been described, the present disclosure is not limited to the example and modification examples mentioned above, and can be implemented in various aspects without departing from the scope of the disclosure.

For example, in the embodiment and the modification example mentioned above, the notification (first approach notification) of the driver's finger coming close to the button region is performed by vibrating the steering 22, but the first approach notification may be performed by vibrating a driver seat or a seat belt, outputting speech from a speaker, causing an in-vehicle predetermined portion (such as, for example, a lamp provided in an instrument panel) to emit light, or irradiating the driver's finger with ultrasonic waves.

Further, in the above-mentioned first modification example, in a state where the driver's finger comes close to the button region, the magnitude of the vibration of the steering 22 is increased when the finger comes close to the button region, but a vibration time may be lengthened, and the number of vibrations may be increased.

In addition, in the above-mentioned second modification example, the touch panel approach vibration pattern is smaller in the magnitude of vibration than the vibration pattern in a case of coming close to the button region, but a vibration time may be shortened, and the number of vibrations may be reduced.

The above disclosure includes the following aspects.

According to a first aspect of the present disclosure, a touch panel type input device includes: a display unit that displays a plurality of input-enabled regions, on which a finger of a user is touchable; an input device that performs an input corresponding to one of the input-enabled regions when it is detected that the finger touches the one of the input-enabled regions; and a first approach notification device that executes a first approach notification for notifying the user of an approach of the finger when the finger is disposed within a first predetermined distance from the one of the input-enabled regions without touching the display unit. The first approach notification device executes the first approach notification by vibrating a part of a compartment of a vehicle other than the input device.

In the input device, even when the user does not visually observe the display unit by receiving the first approach notification, the user can recognize the position of the input-enabled region without touching the display unit. The user can perform an input (touch input) corresponding to the input-enabled region by touching the input-enabled region of the display unit from this state (state the position of the input-enabled region is recognized). As a result, a case does not occur in which an erroneous touch input is performed, and thus a touch input can be easily performed even when the display unit is not visually observed.

Alternatively, the first approach notification device may change a mode of the first approach notification differently according to a type of the one of the input-enabled regions. In this case, when multiple input-enabled regions are displayed on the display unit, the issue of the first approach notification of the same mode even in a case where the finger comes close to any input-enabled region causes the possibility of the user not being likely to recognize the type of input-enabled region. Consequently, the type of input-enabled region can be easily recognized by making the mode of the first approach notification different depending on the type of input-enabled region.

Alternatively, the first approach notification device may change a mode of the first approach notification differently according to a distance between the finger and the one of the input-enabled regions. In this case, since the user's finger does not touch the display unit in a state of coming close to the input-enabled region, the user's finger can take various distances from the input-enabled region. Consequently, by issuing the first approach notification in a mode depending on a distance from the input-enabled region, a distance to the input-enabled region can be easily recognized when the finger comes close to the input-enabled region.

Alternatively, the touch panel type input device may further include: a touch notification device that executes a touch notification for notifying the user of a touch of the finger through a vibration when it is detected that the finger touches the one of the input-enabled regions. When the user attempts to touch the input-enabled region without visually observing the display unit, the user can recognize a touch to the display unit through the tactile sense of the user's finger, but is not likely to recognize whether a touch to the input-enabled region is performed. Consequently, when the user touches the input-enabled region, the user is notified of the touch notification (touch notification is issued) through a vibration, and thus a touch to the input-enabled region and the performing of an input corresponding to the input-enabled region can be easily recognized.

Alternatively, the touch panel type input device may further include: a second approach notification device that executes a second approach notification for notifying the user of an approach of the finger when the finger is disposed within a second predetermined distance from the display unit without touching the display unit. When the user does not visually observe the display unit, there is the possibility of even the position of the display unit not being capable of being essentially recognized. Consequently, the notification (second approach notification) is issued even when the user's finger comes close to the display unit, and thus the user can recognize the position of the display unit without visually observing the display unit.

Alternatively, when a driver drives a vehicle, the part of the compartment of the vehicle may touch the driver. Alternatively, the part of the compartment of the vehicle may be at least one of a steering wheel, a driver seat, and a seat belt of the vehicle. The driver of the vehicle needs to confirm the peripheral situation of the vehicle, and may not be able to be often visually observe the display unit. Even in such a situation, the driver's body touches the steering or the driver seat, and thus the driver can recognize the position of the input-enabled region without touching the display unit by receiving the first approach notification for vibrating the steering or the driver seat. As a result, even during driving, a case does not occur in which an erroneous touch input is performed, and thus it is possible to easily perform a touch input in a state where the display unit is not visually observed.

According to a first aspect of the present disclosure, a touch panel type input method for a display unit that displays a plurality of input-enabled regions, on which a finger of a user is touchable, includes: performing an input corresponding to one of the input-enabled regions when it is detected that the finger touches the one of the input-enabled regions; and executing a first approach notification for notifying the user of an approach of the finger when the finger is disposed within a first predetermined distance from the one of the input-enabled regions without touching the display unit. The executing of the first approach notification includes vibrating a part of a compartment of a vehicle other than a touch panel type device.

In the input method, even when the user does not visually observe the display unit, by receiving the first approach notification, the user can recognize the position of the input-enabled region without touching the display unit. The user can perform an input (touch input) corresponding to the input-enabled region by touching the input-enabled region of the display unit from this state (state the position of the input-enabled region is recognized). As a result, a case does not occur in which an erroneous touch input is performed, and thus a touch input can be easily performed even when the display unit is not visually observed.

It is noted that a flowchart or the processing of the flowchart in the present application includes sections (also referred to as steps), each of which is represented, for instance, as S100. Further, each section can be divided into several sub-sections while several sections can be combined into a single section. Furthermore, each of thus configured sections can be also referred to as a device, module, or means.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A touch panel type input device comprising:
a display unit that displays a plurality of input-enabled regions, on which a finger of a user is touchable;
an input device that performs an input corresponding to one of the input-enabled regions when it is detected that the finger touches the one of the input-enabled regions; and
a first approach notification device that executes a first approach notification for notifying the user of an approach of the finger when the finger is disposed within a first predetermined distance from the one of the input-enabled regions without touching the display unit,
wherein the first approach notification device executes the first approach notification by vibrating a part of a compartment of a vehicle other than the input device.

2. The touch panel type input device according to claim 1, wherein:
the first approach notification device changes a mode of the first approach notification differently according to a type of the one of the input-enabled regions.

3. The touch panel type input device according to claim 1, wherein:
the first approach notification device changes a mode of the first approach notification differently according to a distance between the finger and the one of the input-enabled regions.

4. The touch panel type input device according to claim 1, further comprising:
a touch notification device that executes a touch notification for notifying the user of a touch of the finger through a vibration when it is detected that the finger touches the one of the input-enabled regions.

5. The touch panel type input device according to claim 1, further comprising:
a second approach notification device that executes a second approach notification for notifying the user of an approach of the finger when the finger is disposed within a second predetermined distance from the display unit without touching the display unit.

6. The touch panel type input device according to claim 1, wherein:
when a driver drives a vehicle, the part of the compartment of the vehicle touches the driver.

7. The touch panel type input device according to claim 6, wherein:
the part of the compartment of the vehicle is at least one of a steering wheel, a driver seat, and a seat belt of the vehicle.

8. A touch panel type input method for a display unit that displays a plurality of input-enabled regions, on which a finger of a user is touchable, the touch panel type input method comprising:
performing an input corresponding to one of the input-enabled regions when it is detected that the finger touches the one of the input-enabled regions; and
executing a first approach notification for notifying the user of an approach of the finger when the finger is disposed within a first predetermined distance from the one of the input-enabled regions without touching the display unit,
wherein the executing of the first approach notification includes vibrating a part of a compartment of a vehicle other than a touch panel type device.
